(19) United States
(12) Patent Application Publication
(10) Pub. No.: US 2025/0273261 A1
(43) Pub. Date: Aug. 28, 2025

(54) TWO-TRANSISTOR DRAM CELL AND METHOD OF REFRESHING TWO-TRANSISTOR DRAM CELL

(71) Applicant: POSTECH RESEARCH AND BUSINESS DEVELOPMENT FOUNDATION, Pohang-si (KR)

(72) Inventor: Sung-Woong CHUNG, Pohang-si (KR)

(21) Appl. No.: 18/989,799

(22) Filed: Dec. 20, 2024

(30) Foreign Application Priority Data
Feb. 23, 2024 (KR) 10-2024-0026248

(51) Int. Cl. G11C 11/4096; G11C 5/06; G11C 11/406

(52) U.S. Cl. CPC G11C 11/4096; G11C 5/063; G11C 11/40603

(57) ABSTRACT

Disclosed is a two-transistor (2T) DRAM cell, including a write transistor configured to transmit information of a bit line connected to one terminal of the write transistor to a storage node which is the other terminal of the write transistor in response to a signal of a write word line during a write operation, and a read transistor including a main gate that is activated in response to a voltage of the storage node and an off gate that is formed at a place that comes into contact with the main gate and that is activated in response to a voltage of a source line and configured to transmit a voltage corresponding to the voltage of the storage node to the bit line during a read operation.

### CROSS-REFERENCE TO RELATED APPLICATION

This application claims priority to and the benefit of Korean Patent Application No. 10-2024-0026248 filed on Feb. 23, 2024, the disclosure of which is incorporated herein by reference in its entirety.

### BACKGROUND

### 1. Technical Field

The present disclosure relates to a two-transistor (2T) DRAM cell, and particularly, to a 2T DRAM cell capable of blocking an operation of an unselected cell during a read operation by constructing a gate of a read transistor, among two transistors, as a dual gate including a main gate and an off gate and connecting the terminal of the off gate to a source line and a method of refreshing a 2T DRAM cell.

### 2. Related Art

A 1T1C DRAM cell of the existing 1T1C cell structure, which consists of one transistor T and one capacitor C, is widely used as main memory of a current computer due to advantages of a fast operating speed and a high degree of However, in order to increase the degree of integration. integration, the leakage level of charges stored in the 1T1C DRAM cell is increased as the 1T1C DRAM cell is continuously miniaturized. There is a difficulty in a miniaturization process as the degree of difficulty in the manufacturing of a capacitor having a high integration density and capacitance is also suddenly increased.

Recently, in order to overcome the limit of such a 1T1C DRAM cell, a 2T0C DRAM cell that consists of only two transistors using an oxide semiconductor transistor, such as InGaZnO (IGZO) which is widely used in the display industry, and that does not have a capacitor has been in the spotlight. A leakage current is very low because the bandgap voltage (3.2 eV) of IGZO is about three times the bandgap voltage (1.12 eV) of Si and electrons and holes have a very great asymmetric mobility. Accordingly, even in the 2T0C DRAM cell, it is possible to maintain the storage state of charges corresponding to information for a predetermined time. The fact that the IGZO 2T0C DRAM cell has a data retention time of at least several hours has been widely known.

FIGS. 1A and 1B illustrate a circuit and operation characteristics of a conventional 2T0C DRAM cell.

Referring to the circuit of the 2T0C DRAM cell illustrated in FIG. 1A, it may be seen that the 2T0C DRAM cell includes one write transistor (write TR) (hereinafter referred to as a “WT”) and one read transistor (read TR) (hereinafter referred to as a “RT”).

A write operation of storing information in the 2T0C DRAM cell is performed by charging or discharging charges corresponding to information, which is applied through the WT that is activated based on the voltage level of a write word line WWL and is loaded onto a write bit line WBL, into or from a storage node SN, that is, the gate terminal of the RT. In the following description, charges that are charged into the storage node SN and the storage node voltage VsN of the storage node SN of the 2T0C DRAM cell may be used as the same meaning.

After the write operation, during a read operation, the RT is turned on or turned off based on the level of the storage node voltage VsN stored in the storage node SN.

One terminal of the RT included in the 2T0C DRAM cell is connected to a read bit line RBL, and the other terminal thereof is connected to a read word line RWL. A ground voltage GND is applied to the other terminal of the selected RT of the 2T0C DRAM cell on which a read operation is to be performed through the read word line RWL. Accordingly, the voltage level of the read bit line RBL is changed by a current that flows from the read bit line RBL to the read word line RWL through the selected RT. It is possible to determine information stored in the 2T DRAM cell by sensing a degree that the voltage VRBL of the read bit line RBL has been changed through a sensor unit (not illustrated).

In the following description, it is assumed that when information “H” is stored in the storage node SN, during a read operation, a current well flows from the read bit line RBL to the read word line RWL because a corresponding RT is turned on, and when information “L” is stored in the storage node SN, during a read operation, a current does not flow from the read bit line RBL to the read word line RWL because a corresponding RT is turned off. For example, when expressed in a binary number, “1 (one)” may correspond to “H”, and “0 (zero)” may correspond to “L”.

FIG. 1B illustrates a flow of current during a read operation of a 2T0C DRAM cell array.

FIG. 1B selectively illustrates two 2T0C DRAM cells of

the 2T DRAM cell array for convenience of description. An upper 2T0C DRAM cell of the two 2T0C DRAM cells is a selected cell on which a read operation is to be performed. A lower 2T0C DRAM cell of the two 2T0C DRAM cells is a cell that performs a read operation, and is an unselected cell.

FIG. 1B illustratively shows an undesired current which may be generated during a read operation.

In order to read information stored in a selected 2T DRAM cell (i.e., the upper 2T0C DRAM cell), when the ground voltage GND is applied to only the read word line RWL of the selected 2T DRAM cell and a first voltage V_{DD} is applied to the read word line RWL of an unselected 2T DRAM cell (i.e., the lower 2T0C DRAM cell) in the state in which the read bit line RBL has been precharged with the first voltage V_{DD}, a read current (indicated by an arrow) flows from the read bit line RBL to the read word line RWL based on the information stored in the selected 2T0C DRAM cell. Accordingly, the voltage level of the read bit line RBL is changed. In this case, the first voltage V_{DD} is a voltage source having a relatively higher voltage level than the ground voltage GND.

Hereinafter, in order to help understanding, it is assumed that a current that flows from a selected DRAM cell to a read line is a read current. In this case, the read line includes the read word line RWL described above and a bit line BL described below.

Referring to FIG. 1B, when information “H” is stored in the selected 2T0C DRAM cell (i.e., the upper 2T0C DRAM cell), the voltage level VRBL of the read bit line RBL is reduced by the read current (indicated by a blue arrow). The information stored in the selected 2T0C DRAM cell is determined to be “H” by sensing the reduced voltage level VRBL.

While the information stored in the selected 2T0C DRAM cell is read, an error occurs in the read operation because the voltage level of the read bit line RBL is changed by the read current. Furthermore, while the signal of the selected 2T0C DRAM cell is restored, the voltage of the read bit line RBL moves to the first voltage V_{DD} or the ground voltage GND. At this time, the refresh operation is not performed normally because an undesired current flows into the unselected 2T

DRAM cell. At this time, if the information “H” has also been stored in the unselected 2T0C DRAM cell (i.e., the lower 2T0C DRAM cell, the other terminal of a corresponding RT is connected because the RT of the unselected 2T0C DRAM cell is activated. An undesired current (indicated by the arrow) flows from the read word line RWL having the voltage level of the first voltage V_{DD} toward the read bit line RBL. Such a current (indicated by a red arrow) unwantedly changes the voltage level VRBL of the read bit line RBL. As a result, an error occurs in the read operation.

In order to prevent such an undesired current in the 2T0C DRAM cell array, there is a need for a method of blocking a flow of the unwanted current from the unselected 2T0C DRAM cell.

Furthermore, the 2T0C DRAM cell illustrated in FIGS. 1A and 1B have a disadvantage in that a refresh operation becomes complicated because various voltages need to be applied to at least four lines.

### SUMMARY

Various embodiments are directed to providing a two-transistor (2T) DRAM cell capable of blocking an operation of an unselected cell during a read operation by constructing a gate of a read transistor, among two transistors, as a dual gate including a main gate and an off gate and connecting the terminal of the off gate to a source line.

Various embodiments are directed to providing a 2T DRAM cell array including a plurality of 2T DRAM cells each capable of blocking an operation of an unselected cell during a read operation by constructing a gate of a read transistor, among two transistors, as a dual gate including a main gate and an off gate and connecting the terminal of the off gate to a source line.

Various embodiments are directed to providing a method of refreshing a 2T DRAM cell, which can block an operation of an unselected cell during a read operation by constructing a gate of a read transistor, among two transistors, as a dual gate including a main gate and an off gate and connecting the terminal of the off gate to a source line.

Various embodiments are directed to providing a structure of a 2T DRAM cell capable of blocking an operation of an unselected cell during a read operation by constructing a gate of a read transistor, among two transistors, as a dual gate including a main gate and an off gate and connecting the terminal of the off gate to a source line.

Technical objects to be achieved by the present disclosure are not limited to the aforementioned object, and the other objects not described above may be evidently understood from the following description by a person having ordinary knowledge in the art to which the present disclosure pertains.

In an embodiment, a two-transistor (2T) DRAM cell includes a write transistor configured to transmit information of a bit line connected to one terminal of the write transistor to a storage node which is the other terminal of the write transistor in response to a signal of a write word line during a write operation, and a read transistor including a main gate that is activated in response to a voltage of the storage node and an off gate that is formed at a place that comes into contact with the main gate and that is activated in response to a voltage of a source line and configured to transmit a voltage corresponding to the voltage of the storage node to the bit line during a read operation.

In an embodiment, a two-transistor (2T) DRAM cell array includes the plurality of 2T DRAM cells in which a plurality of bit lines, a plurality of source lines, and a plurality of write word lines are connected according to claim 1. One terminal of a write transistor and one terminal of a read transistor are connected to a corresponding bit line, among the plurality of bit lines, in common. A gate terminal of the write transistor is connected to a corresponding write word line, among the plurality of write word lines. The main gate of the read transistor is connected to the other terminal of the write transistor, and the off gate of the read transistor is connected to the source line.

In an embodiment, a method of refreshing a two-transistor (2T) DRAM cell is a method of refreshing a 2T DRAM cell including a write transistor and a dual gate-read transistor, and includes steps of previously detecting information stored in a DRAM cell to be refreshed by using a bit line connected to the DRAM cell, adjusting a voltage level of the bit line connected to the DRAM cell based on the information stored in the DRAM cell, and writing the adjusted voltage of the bit line in the DRAM cell by activating a write word line that is connected to the DRAM cell.

In a structure of a two-transistor DRAM cell according to one aspect of the present disclosure, the 2T DRAM cell according to claim 1 is implemented to have an inner gate structure, and the off gate of the read transistor is formed under an electrode material with an offset which is an off gate region when a trench corresponding to a storage node having the inner gate structure is filled with the electrode material.

A structure of a two-transistor DRAM cell according to another aspect of the present disclosure is a structure for the two-transistor (2T) DRAM cell according to claim 1, wherein the 2T DRAM cell is implemented to have a planar transistor structure, and when the read transistor is formed, an electrode corresponding to the off gate is formed independently of the main gate.

In a structure for a 2T DRAM cell according to a still another aspect of the present disclosure, in the 2T DRAM cell according to claim 1, the write transistor has a planar structure, and the read transistor has a vertical structure.

Technical objects to be achieved by the present disclosure are not limited to the aforementioned object, and the other objects not described above may be evidently understood from the following description by a person having ordinary knowledge in the art to which the present disclosure pertains.

The two-transistor DRAM cell according to the embodiment of the present disclosure has an advantage in that it can block an operation of an unselected cell during a read operation by constructing a gate of a read transistor, among two transistors, as a dual gate including a main gate and an off gate and connecting the terminal of the off gate to a source line.

Effects of the present disclosure which may be obtained in the present disclosure are not limited to the aforementioned effects, and other effects not described above may be evidently understood by a person having ordinary knowledge in the art to which the present disclosure pertains from the following description.

### BRIEF DESCRIPTION OF THE DRAWINGS

FIGS. 1A and 1B illustrate a circuit and operation characteristics of a conventional 2T0C DRAM cell.

FIG. 2 illustrates an embodiment of a two-transistor (2T) DRAM cell according to an embodiment of the present disclosure.

FIG. 3 is an embodiment of a 2T DRAM cell array using a 2T DRAM cell according to an embodiment of the present disclosure.

FIG. 4 is an embodiment of a method of refreshing a 2T DRAM cell according to an embodiment of the present disclosure.

FIG. 5 illustrates internal voltages of a 2T DRAM cell when a refresh method of a 2T DRAM cell according to an embodiment of the present disclosure is performed.

FIG. 6 illustrates a cross section of a dual gate read transistor that constitutes a 2T DRAM cell according to an embodiment of the present disclosure.

FIG. 7 illustrates cross sections of a 2T DRAM cell array in which two transistors are implemented with planar transistors according to an embodiment of the present disclosure.

FIG. 8 illustrates the progress direction of each pattern illustrated on the right side of the 2T DRAM cell array implemented with the planar transistors illustrated in FIG. 7 according to an embodiment of the present disclosure.

FIG. 9 illustrates a cross-sectional view of a 2T DRAM cell in which two transistors are implemented to have planar and vertical structures according to an embodiment of the present disclosure.

FIG. 10 illustrates a cross-sectional view of a 2T DRAM cell in which two transistors are implemented to have planar and vertical structures according to an embodiment of the present disclosure.

### DETAILED DESCRIPTION

In order to sufficiently understand the present disclosure, operational advantages of the present disclosure, and an object achieved by carrying out the present disclosure, reference needs to be made to the accompanying drawings illustrating embodiments of the present disclosure and contents described with reference to the accompanying drawings.

Hereinafter, embodiments of the present disclosure are described in detail with reference to the accompanying drawings. The same reference numerals presented in the drawings refer to the same members.

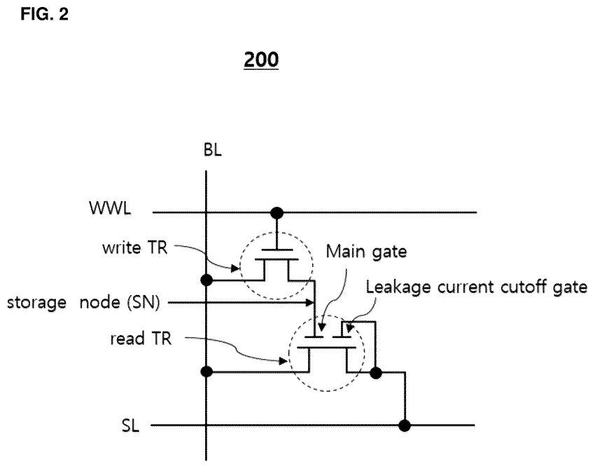

FIG. 2 illustrates an embodiment of a two-transistor (2T) DRAM cell according to an embodiment of the present disclosure.

Referring to FIG. 2, a two-transistor (2T) DRAM cell 200 according to an embodiment of the present disclosure includes a write transistor (write TR) and a read transistor (read TR).

The write TR has one terminal connected to a bit line BL and has a gate terminal connected to a write word line WWL.

The read TR includes two gates, that is, a main gate MG and a sneak current off gate (SCOG) (hereinafter referred to as an “off gate”) that is formed at a place that comes into contact with the main gate MG. The read TR has one terminal connected to the bit line BL and the other terminal connected to a source line SL. The terminal of the main gate MG is connected to the other terminal of the write TR. The terminal of the off gate SCOG is connected to the source line SL.

In the following description, the read TR and a dual gate-transistor read TR are interchangeably used as the same element because the read TR includes the two gate terminals as described above.

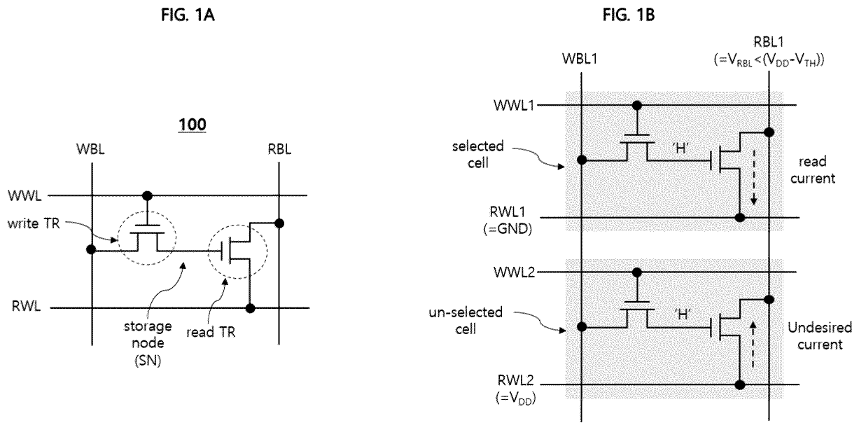

The 2T DRAM cell 200 illustrated in FIG. 2 according to an embodiment of the present disclosure and the conventional 2T0C DRAM cell 100 illustrated in FIGS. 1A and 1B have the following differences.

The read TR that constitutes the conventional 2T0C DRAM cell 100 includes one common gate. In contrast, the read TR that constitutes the 2T DRAM cell 200 proposed by an embodiment of the present disclosure is a dual gate transistor including the main gate MG and the off gate SCOG.

In an embodiment of the present disclosure, the main gate MG and the other terminal of the write TR are combined to form a storage node SN. The read TR according to an embodiment of the present disclosure is different in the function and connection relation of the conventional read TR in that the off gate SCOG is connected to the source line SL.

Finally, the conventional 2T0C DRAM cell 100 illustrated in FIGS. 1A and 1B require four terminals connected to all of the four signal lines WWL, WBL, RWL, and RBL. In contrast, the 2T DRAM cell 200 illustrated in FIG. 2 according to an embodiment of the present disclosure is different from the conventional 2T0C DRAM cell 100 in that the 2T DRAM cell 200 requires only three terminals connected to the three signal lines WWL, BL, and SL.

The three signal lines WWL, WBL, and RWL of the conventional 2T0C DRAM cell 100 illustrated in FIGS. 1A and 1B correspond to the three signal lines WWL, BL, and SL of the 2T DRAM cell 200 illustrated in FIG. 2 according to an embodiment of the present disclosure, respectively. It may be seen that the number of signal lines of the 2T DRAM cell 200 according to an embodiment of the present disclosure is one less than the number of signal lines of the conventional 2T0C DRAM cell 100.

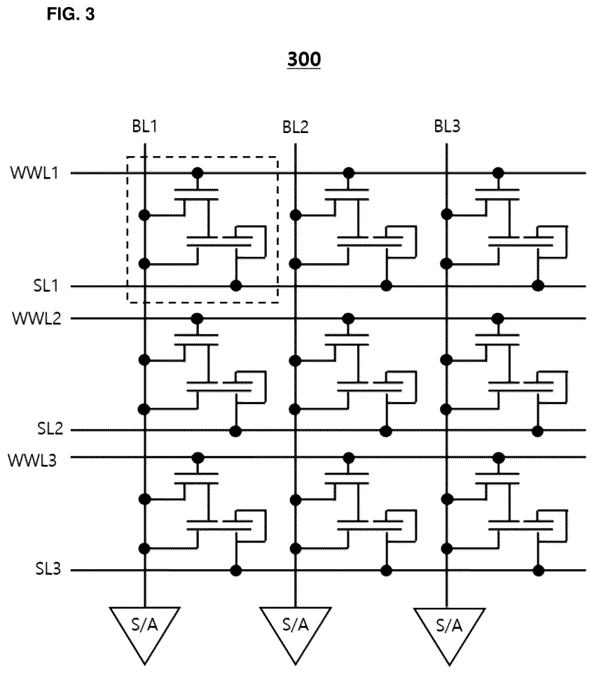

FIG. 3 is an embodiment of a 2T DRAM cell array using a 2T DRAM cell according to an embodiment of the present disclosure.

Referring to FIG. 3, it may be seen that a 2T DRAM cell array 300 is constructed by using only three types of signal lines WWL, BL, and SL.

Hereinafter, an operation of the 2T DRAM cell 200 according to an embodiment of the present disclosure is described.

### Precharge Operation

In order to prevent a sneak current, the 2T DRAM cell 200 maintains a turn-off state during a precharge interval by making the source line SL and the bit line BL have the same voltage level.

### Write Operation

A 2T DRAM cell (hereinafter referred to as a “DRAM cell”) in which information is to be written by applying a voltage that is necessary for a write operation to the write word line WWL and the bit line BL is selected. A ground voltage GND is applied to the source line SL so that the amount of charges charged into the storage node SN is maximized. It has already been described that the storage node SN is a node at which the main gate MG and the other terminal of the write TR are connected.

### Read Operation

In a read operation, a row that is connected to a DRAM cell from which information is to be read is selected by designating the row based on the voltage level of a voltage applied to the source line SL. The voltage level of a voltage applied to the source line SL is equal to or higher than a precharge voltage level of the bit line BL. At this time, when the bit line BL is floated after charged with a precharge voltage, a current flows into the bit line BL only in a DRAM cell in which the voltage of the storage node SN is H (high). When the voltage of the bit line BL rises due to the current flowing into the bit line BL, data that are stored in the DRAM cell are determined to be “1”. When the voltage of the bit line BL does not rise, the data that are stored in the DRAM cell are determined to be “0”. The current that flows into the bit line BL is amplified in a sense amplifier S/A connected to the bit line BL. Data that are stored in a selected DRAM cell are determined based on the results of the amplification in the sense amplifier S/A.

In the following description, it is assumed that the voltage level of the source line SL connected to a selected DRAM cell is high “H” and the voltage level of the source line SL connected to an unselected DRAM cell is low “L”.

### Operation of Selected DRAM Cell

A channel is formed due to the off gate SCOG of a DRAM cell connected to the source line SL because a voltage in a high state is applied to the source line SL connected to the DRAM cell to be selected in order to select the DRAM cell. In this case, the forming of the channel is determined by the main gate MG based on information stored in the storage node SN.

For example, when the information stored in the storage node SN is “H”, a channel is additionally formed by the main gate MG. The channel by the main gate MG is connected to the channel that has already been formed by the off gate SCOG. As a result, the read TR that is constituted with the dual gate is turned on. When the read TR of the selected DRAM cell is turned on, this means that a current corresponding to the information “H” stored in the storage node SN of the selected DRAM cell flows through the bit line BL.

In contrast, when the information stored in the storage node SN is “L”, a channel is not formed by the main gate MG. Although the channel has been formed by the off gate SCOG, the read TR that is constituted with the dual gate is turned off. As a result, current that flows from the selected DRAM cell to the bit line BL will become 0 (zero).

Information stored in the selected DRAM cell is determined based on a voltage that is sensed in the sense amplifier S/A that is connected to the bit line BL as described above.

### Operation of Unselected DRAM Cell

In the case of a DRAM cell in which the voltage level of the source line SL is “L”, the read TR that is constituted with the dual gate is turned off regardless of the forming of a channel by the main gate MG because a channel is not formed by the off gate SCOG connected to the source line SL. Accordingly, in the case of an unselected DRAM cell, a current that flows from the read TR to the bit line BL will become 0 (zero) regardless of information (H or L) stored in the storage node SN.

As described above, in an unselected DRAM cell, any current does not flow into the bit line BL regardless of information (or data) stored in the storage node SN. Accordingly, it can be sufficiently derived that in the 2T DRAM cell array 300, an unselected DRAM cell does not have any influence on a read current that flows into the bit line BL in a selected DRAM cell.

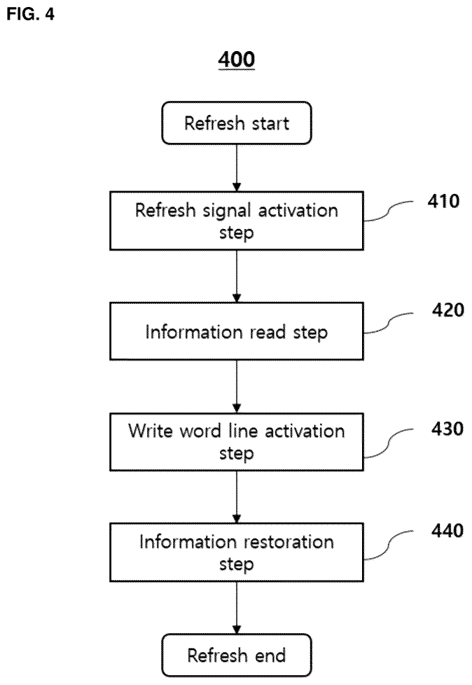

FIG. 4 is an embodiment of a method of refreshing a 2T DRAM cell according to an embodiment of the present disclosure.

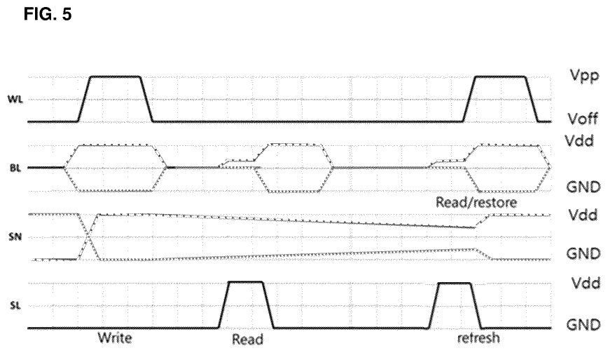

FIG. 5 illustrates internal voltages of a 2T DRAM cell when a refresh method of a 2T DRAM cell according to an embodiment of the present disclosure is performed.

Referring to FIGS. 4 and 5, a refresh method 400 of the 2T DRAM cell (hereinafter referred to as a “DRAM cell”) according to an embodiment of the present disclosure includes a refresh signal activation step 410, an information read step 420, a write word line activation step 430, and an information restoration step 440.

In the refresh signal activation step 410, a refresh pulse signal “refresh” is applied to the source line SL. As illustrated in FIG. 5, the refresh pulse signal “refresh” may be the same as a signal Read that is applied upon read operation.

In the information read step 420, the voltage of the bit line BL connected to a DRAM cell to be refreshed is sensed and amplified by performing a read operation on the DRAM cell to be refreshed.

The amount of charges stored in the storage node SN, which corresponds to information stored in the DRAM cell, is reduced over time. Accordingly, a refresh operation is a process of supplementing the charges of the storage node SN before the amount of the charges stored in the storage node SN is changed and reduced to the extent that the information stored in the DRAM cell is changed.

In an embodiment of the present disclosure, information stored in a DRAM cell to be refreshed is sensed based on the voltage level of the bit line BL related to the DRAM cell. In general, although information “H” is stored, the first amount of charges stored in the storage node SN will be reduced at a predetermined ratio due to an influence, such as leakage, when a predetermined time elapses after the information is written. When a read operation is performed on the DRAM cell in the state in which the amount of charges stored in the storage node SN has been reduced by a certain quantity, the voltage level of the bit line BL may be higher than a voltage level corresponding to “L” although the voltage level of the bit line BL is lower than a voltage level corresponding to “H”.

In the information read step 420, the voltage level of the bit line BL connected to the DRAM cell to be refreshed is previously sensed and amplified so that information stored in the DRAM cell is confirmed again in order to improve the accuracy of refresh.

The write word line activation step 430 is performed by applying a voltage Vₚₚ to a write word line WL. It is preferred that the write word line WL is activated after a lapse of a minimum time during which the information stored in the storage node SN can be read and amplified in the information read step 420.

In the information restoration step 440 or the restoration step, information that needs to be stored in the DRAM cell is confirmed again and restored based on the voltage level of the bit line BL. That is, a voltage having a voltage level corresponding to the voltage level of a voltage that needs to be stored in the DRAM cell is applied from the bit line BL. For convenience of description, it is assumed that the voltage level of the bit line BL corresponding to “H” is V_{DD}, the voltage level of the bit line BL corresponding to “L” is the ground voltage GND, and the voltage levels have a relation of V_{DD}>GND.

In other words, in the information restoration step 440, when the voltage level of the bit line BL, which is first sensed in the information read step 420, is lower than V_{DD}, for example, but is a voltage level corresponding to “H”, the voltage level of the bit line BL related to the DRAM cell is amplified and adjusted to become V_{DD}. When the DRAM cell has a voltage level that is higher than GND, but corresponds to “L”, the voltage level of the bit line BL will be amplified and adjusted to become the ground voltage GND. That is, as illustrated in FIG. 5, while the write word line WL is turned on, the voltage level that is read in the bit line is re-written (i.e., restored) in a corresponding DRAM cell.

Furthermore, as illustrated in FIG. 5, the start point of a pulse signal that is applied to the source line SL when refresh is started and a start point at which a pulse signal that is applied to a word line WL in order to complete the information restoration step 440 is activated are different from each other. The start point at which the pulse signal that is applied to the word line WL is activated is slightly later than the start point of the pulse signal that is applied to the source line SL.

The conventional DRAM cell requires the read bit line RBL and the write bit line WBL, whereas the 2T DRAM cell according to an embodiment of the present disclosure has the following advantages because one bit line BL is used.

In the conventional DRAM cell, in a process of sensing information stored in the conventional DRAM cell through the bit line BL, a change in the voltage of the bit line BL essentially occurs. Such a change in the voltage generates a difference from the voltage of the source line SL so that a current flows into all of DRAM cells that share the bit line BL and in each of which information stored therein is “H”. Accordingly, there is a problem in that the sensing of the bit line BL is influenced or the time that is taken for a write voltage to be saturated up to V_{DD} or GND is increased. Furthermore, there is a problem in that time, power consumption, a switch, and a command circuit for charging two bit lines for writing (or restoration) are additionally required because the bit line of the write transistor needs to be amplified again after one bit line is amplified by the sense amplifier.

In a process of writing information “H”, the read TR is turned on as the potential of the storage node SN is increased and thus a current starts to flow from the bit line BL to the source line SL. Accordingly, the write speed will be reduced and power consumption will be increased because the voltage of the bit line BL that is used to charge the storage node SN is distributed to the source line SL. In particular, it is possible to prevent a current from continuously flowing into the read TR during a refresh process or a write process by the off gate SCOG.

In FIG. 5, Voff indicated in the word line WL may have the same voltage level as the ground voltage GND, may have a lower voltage level than the ground voltage GND. Vpp may have a higher voltage level than the voltage V_{DD}. Hereinafter, a structure of the 2T DRAM cell illustrated in FIG. 2 in a wafer state according to an embodiment of the present disclosure is described.

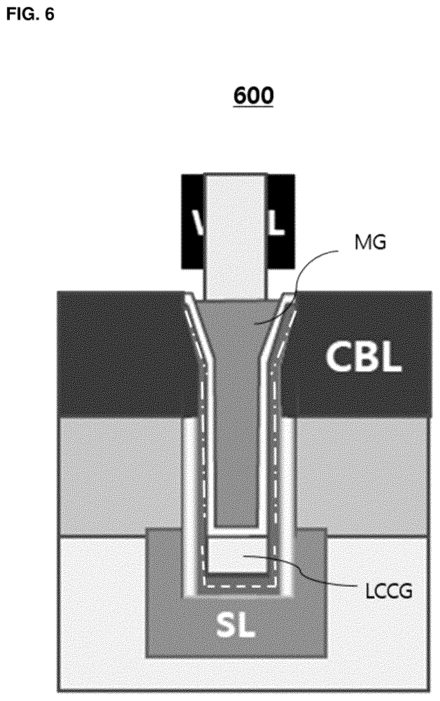

FIG. 6 illustrates a cross section of a dual gate read transistor that constitutes a 2T DRAM cell according to an embodiment of the present disclosure.

Referring to FIG. 6, a 2T DRAM cell 600 proposed by an embodiment of the present disclosure may be formed by additionally forming an off gate SCOG in a read transistor structure having an inner gate type and connecting the off gate SCOG to a source line SL.

When a trench corresponding to a storage node SN or a main gate MG is filled with an electrode material, the trench may be formed under the electrode material in a way to fill the trench with an offset (i.e., SCOG), that is, an off gate region.

For example, after a dielectric thin film corresponding to a gate insulating film of the off gate SCOG is deposited before a thin film channel is deposited, a second channel (a dotted line) may be formed by the off gate SCOG connected to a first channel (indicated by an alternate long and short dash line) by the main gate MG through a sidewall etching process.

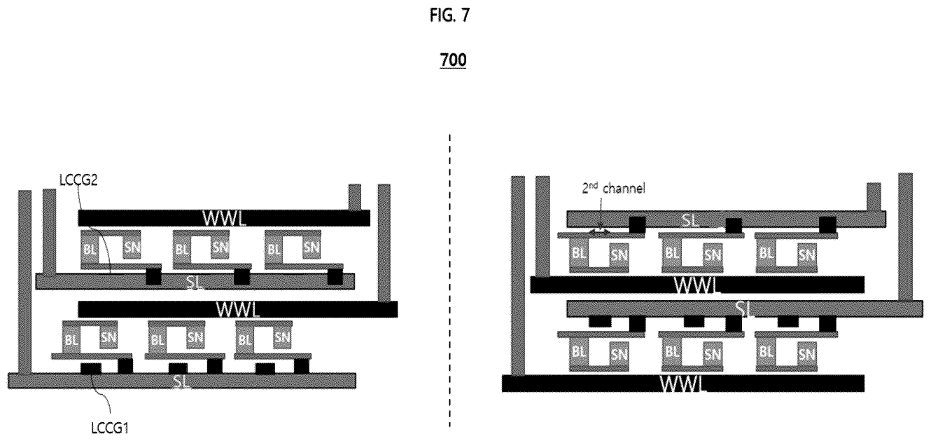

FIG. 7 illustrates cross sections of a 2T DRAM cell array in which two transistors are implemented with planar transistors according to an embodiment of the present disclosure.

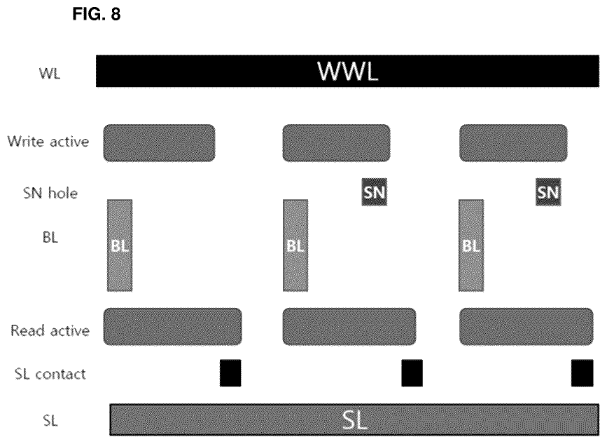

FIG. 8 illustrates the progress direction of each pattern illustrated on the right side of the 2T DRAM cell array implemented with the planar transistors illustrated in FIG. 7 according to an embodiment of the present disclosure.

The left and right cross sections of FIG. 7 correspond to the same circuit, and are divided depending on whether a source line SL is first formed (left side) and a write word line WWL is first formed (right side) in order of a manufacture process of the 2T DRAM cell array.

Referring to FIGS. 7 and 8, the 2T DRAM cell array implemented with the planar transistors according to an embodiment of the present disclosure includes a total of six 2T DRAM cells in which three 2T DRAM cells form two layers. The write word line WWL and the source line SL are formed up and down on a plane of the drawing on the left side and right side of the 2T DRAM cell array. A bit line BL is formed in a direction perpendicular to the plane of the drawing.

First, referring to the left drawing of FIG. 7, the off gate SCOG connected to the source line SL may be separately formed (SCOG1), but may not be separately formed (SCOG2). In this case, the reason why the off gate SCOG is not separately formed is that the off gate SCOG2 can be formed in a place where the space between the storage node SN and the bit line BL and the source line SL are overlapped in common. A 2^{nd} channel may be formed only when the place where the space between the storage node SN and the bit line BL and the source line SL are overlapped in common has only to be separated by an insulator.

The description of the left drawing may be adopted for the right drawing of FIG. 7 without any change. In the right drawing, a channel that is formed by the off gate SCOG2 is expressed as a 2^{nd} channel.

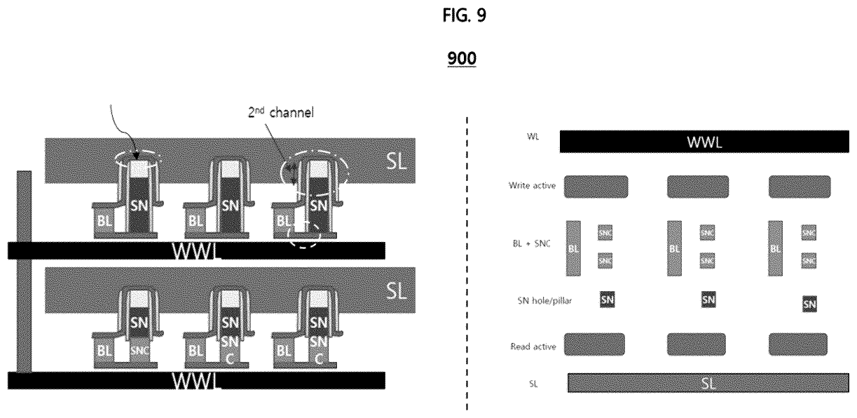

FIG. 9 illustrates a cross-sectional view of a 2T DRAM cell in which two transistors are implemented to have planar and vertical structures according to an embodiment of the present disclosure.

The left side of FIG. 9 is a cross-sectional view of the 2T DRAM cell according to an embodiment of the present disclosure. The right side of FIG. 9 illustrates the progress direction of each pattern that constitutes the 2T DRAM cell.

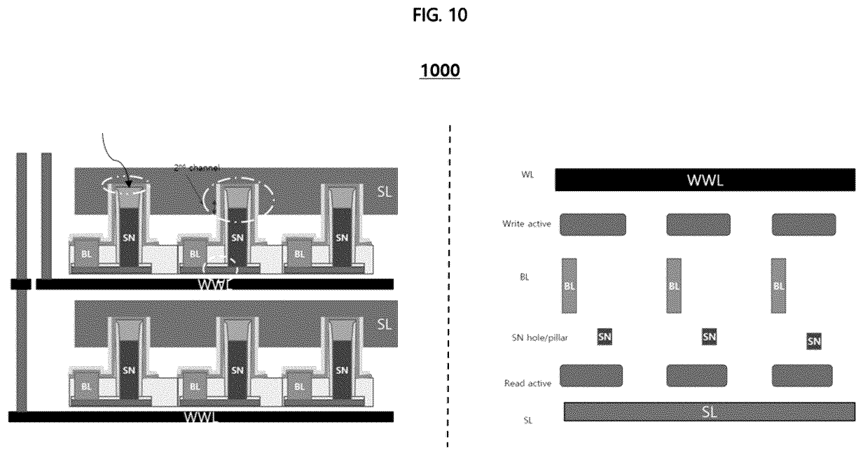

FIG. 10 illustrates a cross-sectional view of a 2T DRAM cell in which two transistors are implemented to have planar and vertical structures according to an embodiment of the present disclosure.

The left side of FIG. 10 is a cross-sectional view of the 2T DRAM cell according to an embodiment of the present disclosure. The right side of FIG. 9 illustrates the progress direction of each pattern that constitutes the 2T DRAM cell.

Referring to FIGS. 9 and 10, it may be seen that a write transistor has the planar structure (indicated by a dotted circle) and a read transistor has the vertical structure (indicated by an alternate long and short dash line circle).

Descriptions of the right patterns of FIGS. 9 and 10 are replaced with the description of FIG. 8.

A difference between the embodiments of FIGS. 9 and 10 lies in an example (FIG. 9) in which a read transistor pattern (indicated by a two-point chain circle) is etched and an example (FIG. 10) in which the read transistor pattern is not etched, before an insulator is formed between a source line SL and a read transistor pattern are formed after a storage node SN and the read transistor pattern (indicated by a two-point chain circle) are formed, as indicated by arrows.

As described above, it may be seen that the 2T DRAM cell 200 illustrated in FIG. 2 according to an embodiment of the present disclosure may be implemented in various ways, such as the example (FIG. 2) in which the 2T DRAM cell 200 is implemented to have the inner gate structure, the examples (FIGS. 7 and 8) in which the main gate MG and the off gate SCOG, that is, two transistors, are each implemented to have the planar structure, and the examples (FIGS. 9 and 10) in which the main gate MG has the planar structure and the off gate SCOG has the vertical structure.

The technical spirit of the present disclosure has been described along with the accompanying drawings, but this exemplarily describes preferred embodiments of the present disclosure and is not intended to limit the present disclosure. Furthermore, it is evident that any person having ordinary knowledge in the field to which the present disclosure s may modify and imitate the present disclosure without departing from the category of the technical spirit of the present disclosure.

What is claimed is:

1. A two-transistor (2T) DRAM cell comprising:
a write transistor configured to transmit information of a bit line connected to one terminal of the write transistor to a storage node which is the other terminal of the write transistor in response to a signal of a write word line during a write operation; and
a read transistor comprising a main gate that is activated in response to a voltage of the storage node and an off gate that is formed at a place that comes into contact with the main gate and that is activated in response to a voltage of a source line and configured to transmit a voltage corresponding to the voltage of the storage node to the bit line during a read operation.

2. The 2T DRAM cell of claim 1, wherein:
the read transistor has one terminal connected to the bit line and the other terminal connected to the source line,
a terminal of the off gate is connected to the source line, and
a terminal of the main gate is connected to the storage node.

3. The 2T DRAM cell of claim 2, wherein during the read operation,
a second channel that is formed by the off gate is activated, and
a first channel that is formed by the main gate is activated or inactive based on an information stored in the storage node.

4. The 2T DRAM cell of claim 3, wherein:
in the state in which the second channel has been activated, the value stored in the storage node is a logic high when the first channel is activated, and
in the state in which the second channel has been activated, the value stored in the storage node is a logic low when the first channel is not activated.

5. A two-transistor (2T) DRAM cell array comprising:
the plurality of 2T DRAM cells in which a plurality of bit lines, a plurality of source lines, and a plurality of write word lines are connected according to claim 1,
wherein one terminal of a write transistor and one terminal of a read transistor are connected to a corresponding bit line, among the plurality of bit lines, in common,
a gate terminal of the write transistor is connected to a corresponding write word line, among the plurality of write word lines, and
the main gate of the read transistor is connected to the other terminal of the write transistor, and the off gate of the read transistor is connected to the source line.

6. A method of refreshing a two-transistor (2T) DRAM cell comprising a write transistor and a dual gate-read transistor, the method comprising:
a refresh signal activation step of applying a refresh pulse signal stored in a DRAM cell to be refreshed by using a source line connected to the DRAM cell;
an information read step of detecting and amplifying information stored in the DRAM cell to which the refresh pulse signal has been applied;
a step of activating a write word line connected to the DRAM cell; and
a step of confirming information to be refreshed based on a voltage level of a bit line connected to the DRAM cell and restoring the information to be refreshed to information in the DRAM cell by applying a voltage corresponding to the information to be refreshed to the bit line.

7. The method of claim 6, wherein in the step of restoring the information,
when the detected information of the DRAM cell is a logic high, a first voltage is formed in the bit line, and
when previously detected information of the DRAM cell is a logic low, a second voltage is formed in the bit line.

8. The method of claim 7, wherein the first voltage has a relatively higher voltage level than the second voltage.

9. A structure of a two-transistor (2T) DRAM cell, wherein:
the 2T DRAM cell according to claim 1 is implemented to have an inner gate structure, and
the off gate of the read transistor is formed under an electrode material with an offset which is an off gate region when a trench corresponding to a storage node having the inner gate structure is filled with the electrode material.

10. A structure for the two-transistor (2T) DRAM cell according to claim 1, wherein the 2T DRAM cell is implemented to have a planar transistor structure, and when the read transistor is formed, an electrode corresponding to the off gate is formed independently of the main gate.

11. The structure of claim 10, wherein when the read transistor is formed, the off gate is formed by forming an insulator in a region corresponding to an off gate region.

12. A structure for the two-transistor (2T) DRAM cell according to claim 1, wherein the write transistor has a planar structure, and the read transistor has a vertical structure.

13. The method of claim 6, wherein a start point at which a voltage applied to a word line in the step of restoring the information is activated is later than timing at which the refresh pulse signal is activated.
